(19) United States
(12) Patent Application Publication
(10) Pub. No.: US 2008/0246459 A1
(43) Pub. Date: Oct. 9, 2008

(54) Common-Mode Surge Suppression

(76) Inventor: Thomas M. Ingman, Somis, CA (US)

Correspondence Address: SoCAL IP LAW GROUP LLP, 310 N. WESTLAKE BLVD. STE 120, WESTLAKE VILLAGE, CA, 91362, US

(21) Appl. No.: 11/697,156

(22) Filed: Apr. 5, 2007

(51) Int. Cl. H01F 19/00

(52) U.S. Cl. 323/355

(57) ABSTRACT

There is disclosed a filter for reducing electromagnetic interference generated by a power converter. The filter may include a common-mode inductor having first and second windings on a common core. The first and second windings may be connected between first and second power input lines and first and second inputs to the power converter, respectively. A series combination of a resistor and a voltage limiting device may be connected in parallel with the first winding.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

1. Field

This disclosure relates to electromagnetic interference filters and surge suppressors for use in power converters.

2. Description of the Related Art

Electronic equipment, including power converters, may need to comply with regulations limiting the electromagnetic interference (EMI) that may be radiated or emitted by the equipment. International standards for EMI limits are developed by the Comité International Spécial des Perturbations Radioélectriques (CISPR) and adopted by regional and national authorities. In the U.S., an applicable regulation is FCC Part 15. In Europe the standard for DC power converters is EN 55022.

Since some electromagnetic interference is inherently generated in switching-mode power converters, power converters may incorporate an EMI filter between the input power source and the converter to reduce EMI that is conducted on the power lines. Conducted EMI is generally considered to be comprised of two types of noise: common-mode noise appearing as a voltage between both power supply lines and ground, and differential-mode noise appearing as a voltage between the power supply lines.

Electronic equipment including power converters may also have to comply with various environmental requirements including the ability to withstand input voltage surges or transients. Input voltage surges are also typically divided into two types: common-mode voltage surges appearing as a voltage between power supply lines and ground, and differential-mode voltage surges appearing as a voltage between the power supply lines. In particular, electronic equipment may be required to survive lightning surge tests such as GR-1089-CORE for telecommunications equipment and EN 61000-4-5 in Europe. Some types of equipment may also have to comply with safety standards and requirements which may include requirements for very high impedance and extremely low leakage current between the equipment and ground.

### DESCRIPTION OF THE DRAWINGS

FIG. 1A is a schematic diagram of a prior art electromagnetic interference filter.

FIG. 1B is a schematic diagram of a prior art electromagnetic interference filter.

FIG. 2 is a graph of a voltage surge test waveform.

FIG. 3 is a graph of a voltage surge waveform.

FIG. 4 is a schematic diagram of an electromagnetic interference filter.

FIG. 5 is a schematic diagram of an electromagnetic interference filter.

FIG. 6 is a schematic diagram of an electromagnetic interference filter.

### DETAILED DESCRIPTION

Throughout this description, the embodiments and examples shown should be considered as exemplars, rather than limitations on the apparatus and methods disclosed or claimed.

Description of Apparatus

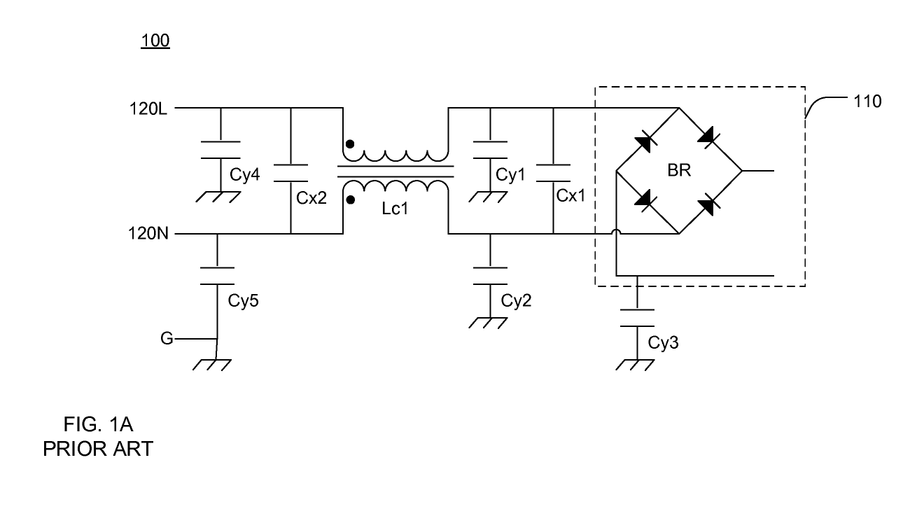

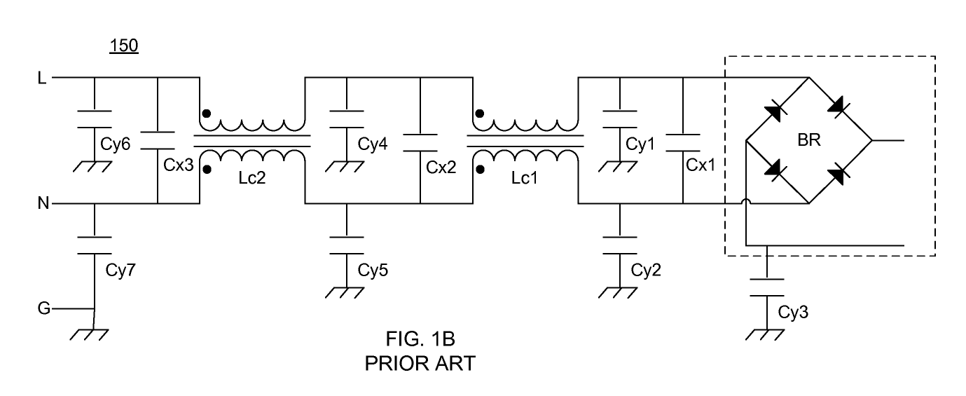

Referring now to FIG. 1A, an exemplary prior art EMI filter 100 may be disposed between an AC power line 120L/N and a DC power converter 110. The AC power line may include two conductors 120L, 120N supplying AC power and a third ground conductor G. The EMI filter 100 may include a common-mode inductor Lc1 connected between the AC power line 120L/N and the DC power converter 110, and a plurality of capacitors. A common-mode inductors is a well-known type of component that has high impedance for common-mode EMI and low impedance for the differential current that flows from the power line to the power converter. Common-mode inductors are constructed with two or three windings on one core. These windings are connected such that the current that flows into the DC power converter 110 through one winding flows out through the second winding, producing equal but opposing fluxes in the core of the common-mode inductor Lc1. The net effect is that the flow of power from the power line 120L/N to the DC power converter 110 produces no net flux in the core. Thus common-mode inductors can be made with relatively small core sizes for their rated current and still provide high impedance for common-mode noise current flowing in both windings.

Capacitors Cx1 and Cx2 may be connected across the AC line on either side of the common-mode inductor Lc1. Cx1 and Cx2 are commonly called “X capacitors” and are adapted specifically for use across the AC line. X capacitors are designed to withstand continuous AC current flow, to have very low loss at the frequency of the AC power input, to have low impedance at the switching frequency of the DC power converter, and to be able to withstand the peak transient voltage that may occur between the AC power conductors.

Capacitors Cy1, Cy2, Cy4, and Cy5 may be connected from the AC power conductors to the ground. These capacitors are commonly called “Y capacitors”. Y capacitors are designed to have very low leakage current, to have low impedance at the switching frequency of the DC power converter, and to be able to withstand the peak transient voltage that may occur between the AC power conductors and ground. The DC power converter 110 may include a bridge rectifier BR that converters the AC line voltage to a DC voltage. Another Y capacitor Cy3 may be connected from one side of the output from the bridge rectifier BR to ground.

FIG. 1B is a schematic diagram of a second prior art EMI filter 150 that adds another stage of filtration comprising a second common-mode inductor Lc2 and additional capacitors Cx3, Cy6, and Cy7. The two-stage EMI filter 150 of FIG. 1B may provide increased EMI attenuation compared to the single-stage EMI filter 100 of FIG. 1A. Depending on requirements, an EMI filter may use more or fewer components than the examples of FIG. 1A and FIG. 1B. In particular, not all of the capacitors shown may be used, and one or more additional inductors may be added.

Although the examples of FIG. 1A and FIG. 1B show an AC power line input, similar filters may be used with power converters operating from a DC power supply. Power converters with DC input are commonly used in telecommunications equipment cabinets (commonly using a 48 volt DC input power), aircraft (commonly either a 28-volt or a 270-volt DC input power) and other applications.

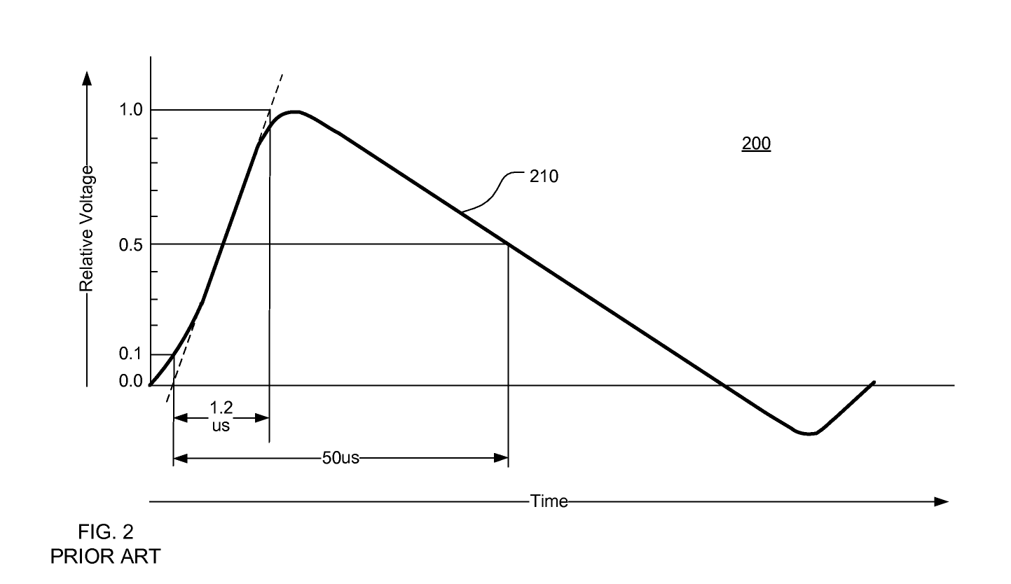

Power converters may be required to withstand voltage surges and transients on the input power lines without damage. FIG. 2 is a graph 200 of a common-mode voltage surge waveform 210. The waveform 210 is representative of the waveforms used for lightning surge tests under the GR-1089 CORE standard for telecommunications equipment and EN 61000-4-5 standard for equipment used in Europe. The test requirements of these two standards differ primarily in the specifications for the rise and fall times of the waveform 210. Some equipment may be required to withstand the voltage waveform 210, applied between a power input line and ground, with a peak voltage of 2000 volts.

Power converters may incorporate voltage limiting devices, also called transient suppressors or surge suppressors, to absorb input voltage surges without damage to the power converter. Within this description, a voltage limiting device is any component that exhibits an abrupt increase in conductivity when the voltage across the device exceeds a threshold voltage. The threshold voltage of a voltage limiting device is determined during manufacture. Voltage limiting devices are available with thresholds ranging from a few volts to hundreds of volts and higher. Voltage limiting devices include back-to-back connected Zener diodes, silicon transient suppressors, transorbs, voltage variable resistors or varistors, gas discharge tubes, or any other component that exhibits an abrupt increase in conductivity when the voltage across the device exceeds a predetermined threshold voltage.

Differential-mode voltage surges applied between pairs of power input lines may be absorbed and limited by voltage limiting devices connected in parallel with one or more X capacitors in the example filters of FIG. 1A and FIG. 1B. Common-mode voltage surges applied between one or more power input lines and ground may be absorbed and limited by voltage limiting devices connected in parallel with one or more Y capacitors in the example filters of FIG. 1A and FIG. 1B. However, safety standards on certain equipment, including medical equipment, may require extremely high resistance and low leakage current between the circuitry of the power converter and ground. A requirement for extremely high resistance and low leakage current may preclude the incorporation of common-mode voltage limiting devices.

Power converters that do not incorporate common-mode surge limiting components must be designed to withstand common-mode voltage surges without failure and without significant disruption of the power converter's normal function. Although one or more Y capacitors may be the only components physically connected between the circuitry of a power converter and ground, every component and circuit trace within the power converter may have a stray capacitance to ground. The application of a voltage surge between the power input lines and ground will cause current to flow through each of the stray capacitances. The current flow in each stray capacitance will be defined by the well-known formula I=C dV/dt, where I is the current flow, C is the capacitance, and dV/dt is the rate of change of the surge voltage. Assuming the surge voltage rises linearly with time, the magnitude of the current flow will be roughly proportional to the peak amplitude of the voltage surge and inversely proportional to the rise time of the voltage surge. Clearly, limiting the peak amplitude and maximizing the rise time of the surge voltage may simplify the problem of designing the power converter to withstand common-mode voltage surges.

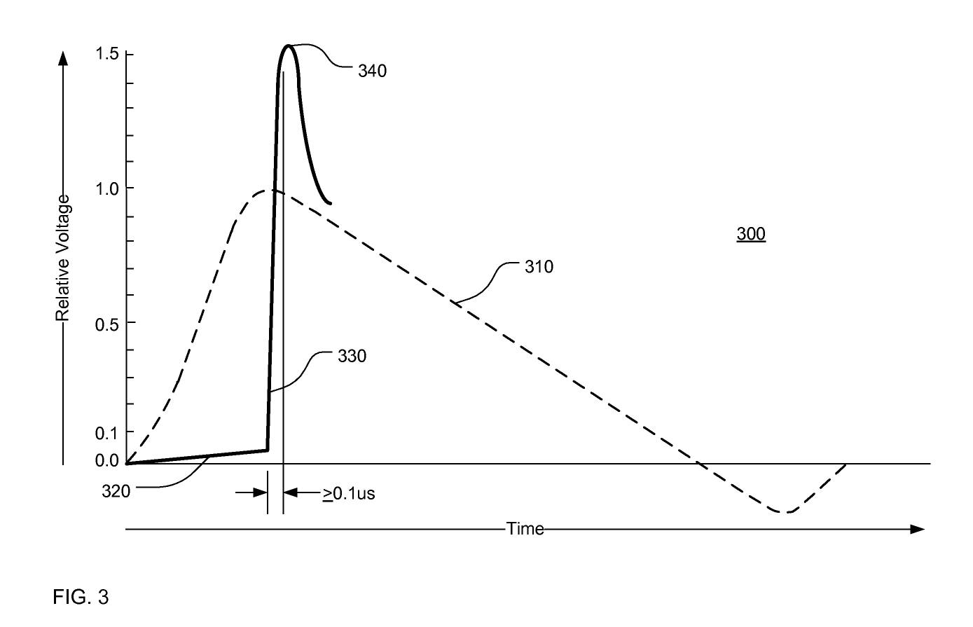

Referring back to FIG. 1A, the common-mode inductor Lc1 and the Y capacitors may form an L-C low pass filter that, at least initially, may reduce the amplitude of a common-mode voltage surge applied between the power input lines 120 and the ground. However, as illustrated in FIG. 3, the common-mode inductor may, in some circumstances, greatly exacerbate the current that flows through the stray capacitances.

FIG. 3 shows a graph 300 of the voltage waveform 320/330/340 across one of the capacitors Cy1-Cy3 in response to a common-mode voltage transient shown as dashed line 310. The voltage waveform 320/330/340 is representative of measured data but has been exaggerated into three distinct regions 320/330/340 for ease of description. Note that the stray capacitances between the power converter circuitry and ground are essentially in parallel with the Y capacitors. Thus the currents that flow through the stray capacitances into the circuitry of the power converter will be determined, in part, by the peak amplitude and the rise time of the waveform 320/330/340.

Initially, the inductance of common-mode inductor Lc1 may limit the current that flows through Lc1 to charge the Y capacitors. During this period (see waveform region 320), the voltage across the Y capacitors may rise much slower than the input voltage surge 310. During this period, a substantial voltage may build up across Lc1. At some point, the current flow through the windings of Lc1 may induce a sufficient magnetic field in the core of Lc1 to cause the core to saturate. If the core of Lc1 saturates, the permeability of the core material will drop substantially. The drop in core permeability will cause a corresponding decrease in the inductance of Lc1, and the current flow through the windings of Lc1 will increase precipitously. In response to the increased current flow, the voltage across the Y capacitors will increase rapidly (see waveform region 330). The rise time of the voltage across the Y capacitors may be as little as 0.1 microsecond, more than an order of magnitude less than the rise time of the voltage surge 310.

After the core of common-mode inductor Lc1 saturates, the inductance of Lc1 will drop to a low, but finite, value such that some energy is still stored in Lc1. The energy stored in Lc1 may cause current to flow into the Y capacitors even after the input voltage surge 310 has peaked. Thus the peak voltage across the Y capacitors (see waveform region 340) may exceed, or overshoot, the peak surge voltage by 50% or more.

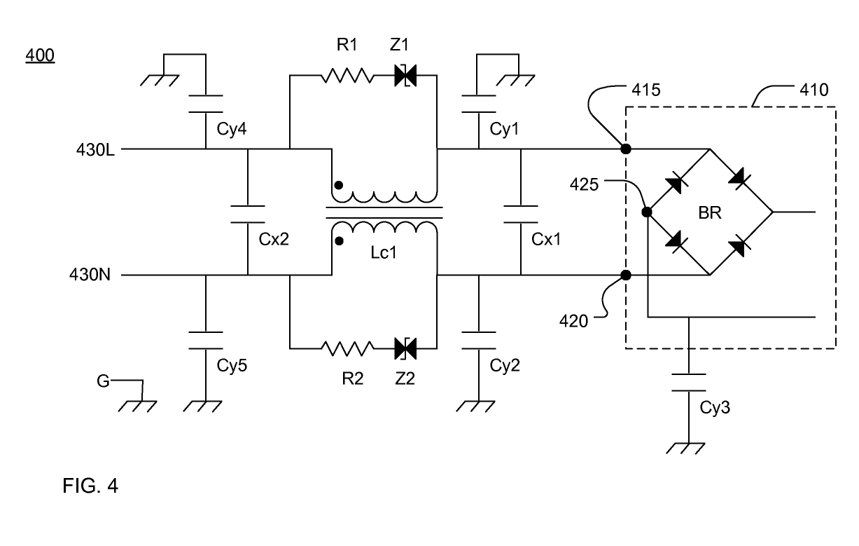

FIG. 4 is a schematic diagram of a filter 400 generally similar to the filter 100 of FIG. 1A. A common-mode inductor Lc1 has first and second windings on a common core. The first winding of common-mode inductor Lc1 may be connected between a first power input line 430L and a first input 415 to a power converter 410. The filled bullets at 415, 420, and 425 are provided for ease of identification and do not connote a physical terminal or component. The second winding of common-mode inductor Lc1 may be connected between a second power input line 430N and a second input 420 to the power converter 410. The power input lines 430L and 430N may define an AC power source or a DC power source.

A first resistor R1 and a voltage limiting device Z1 may be connected in series, and the series combination may be connected in parallel with the first winding of common-mode inductor LC1. The voltage limiting device Z1 may be a Zener diode, a silicon transient suppressor, a transorb, a voltage variable resistor or varistor, a gas discharge tube, or any other component that exhibits an abrupt increase in conductivity when the voltage across the device exceeds some threshold voltage. The voltage limiting device Z1 may have a threshold voltage that is much smaller than the anticipated amplitude of common-mode voltage surges that may be applied to the power input lines 430L/N. The series combination of voltage limiting device Z1 and resistor R1 may limit the voltage that builds up across the first winding of common-mode inductor Lc1 and may provide an alternate path for current to charge Y capacitors, if present. The presence of voltage limiting device Z1 may or may not prevent saturation of the core of common-mode inductor Lc1.

The voltage limiting device Z1 may have a threshold voltage that is larger than the noise voltage developed across the first winding of common-mode inductor during normal operation of the filter 400. The voltage limiting device Z1 may be nonconductive during normal operation of the filter 400.

The filter 400 may include an X capacitor Cx1 connected between the first input to the power converter 415 and the second input to the power converter 420. The filter 400 may include a Y capacitor Cy1 connected between the first input to the power converter 415 and ground. The filter 400 may include a Y capacitor Cy2 connected between the second input to the power converter 420 and ground. The filter 400 may include a Y capacitor Cy3 connected between ground and an output 425 of a bridge rectifier BR within power converter 410.

The resistance of resistor R1 may function to limit the current flow through the voltage limiting device Z1. The resistance of resistor R1 and the capacitance of capacitor Cy1 may be selected such that resistor R1 and capacitor Cy1 have a time constant less than or equal to the rise time of the largest anticipated common-mode voltage surge waveform. Resistor R1 and capacitor Cy1 have a time constant between 33% and 100% of the rise time of the largest anticipated common-mode voltage surge waveform. The resistance of resistor R1 may be selected empirically to minimize the voltage transient measured between the input 415 or 420 to power converter 410 and ground.

A second resistor R2 and a second voltage limiting device Z2 may be connected in series, and the series combination may be connected in parallel with the second winding of common-mode inductor LC1. The voltage limiting device Z2 may be the same or a different type of device from voltage limiting device Z1. The voltage limiting device Z2 may have a threshold voltage that is the same or different from the threshold voltage of voltage limiting device Z1. Resistor R2 may have a resistance that is the same or different from the resistance of resistor R1.

Another voltage limiting device (not shown) may be connected in parallel with capacitor Cx1 to limit and absorb differential-mode voltage surges.

The filter 400 may include additional capacitors, such as capacitor Cx2, Cy4, and Cy5, or fewer capacitors. The filter 400 may including another filter stage including a second common-mode inductor, similar to the second stage of the filter 150 shown in FIG. 1B.

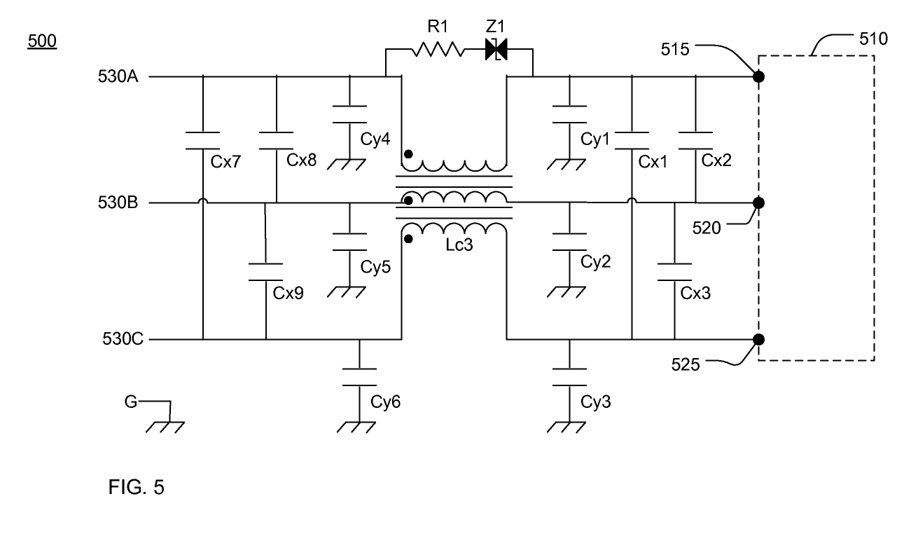

FIG. 5 is a schematic diagram of another EMI filter 500. A common-mode inductor Lc3 may have first, second, and third windings on a common core. The first winding of common-mode inductor Lc3 may be connected between a first power input line 530A and a first input 515 to a power converter 510. The filled bullets at 515, 520, and 525 are provided for ease of identification and do not connote a physical terminal or component. The second winding of common-mode inductor Lc3 may be connected between a second power input line 530B and a second input 520 to the power converter 510. The third winding of common-mode inductor Lc3 may be connected between a third power input line 530C and a third input 525 to the power converter 510. The power input lines 530A/B/C may define a three-phase AC power source.

A first resistor R1 and a voltage limiting device Z1 may be connected in series, and the series combination may be connected in parallel with the first winding of common-mode inductor Lc3. Voltage limiting device Z1 and the threshold of voltage limiting device Z1 may be selected as previously described in conjunction with FIG. 4. A second resistor and a second voltage limiting device in series (not shown) may be connected in parallel with the second winding of common-mode inductor Lc3. Similarly, a third resistor and a third voltage limiting device in series (not shown) may be connected in parallel with the third winding of common-mode inductor Lc3.

The filter 500 may include a plurality of capacitors, and may include more or fewer capacitors than those shown in FIG. 5.

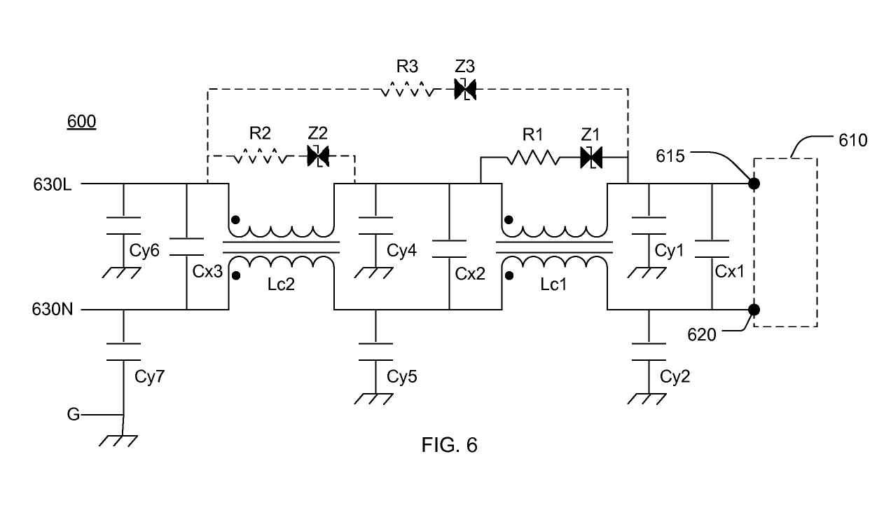

FIG. 6 is a schematic diagram of another EMI filter 600 generally similar to the filter 150 of FIG. 1B. A first common-mode inductor Lc1 may have first and second windings on a common core. A second common-mode inductor Lc2 may have first and second windings on a common core. The first windings of common-mode inductors Lc1 and Lc2 may be connected between a first power input line 630L and a first input 615 to a power converter 610. The filled bullets at 615, and 620 are provided for ease of identification and do not connote a physical terminal or component. The second windings of common-mode inductors Lc1 and Lc2 may be connected between a second power input line 630N and a second input 620 to the power converter 610. The power input lines 630A/B/C may define a single-phase AC power source or a DC power source.

A first resistor R1 and a first voltage limiting device Z1 may be connected in series, and the series combination may be connected in parallel with the first winding of the first common-mode inductor Lc1. Voltage limiting device Z1 and the threshold of voltage limiting device Z1 may be selected as previously described in conjunction with FIG. 4. A second resistor R2 and a second voltage limiting Z2 device in series, shown in dashed lines, may be connected in parallel with the first winding of the second common-mode inductor Lc2. Alternatively, a resistor R3 and a voltage limiting device Z3 in series (also shown in dashed lines) may be connected in parallel with the series combination of the first winding of common-mode inductor Lc1 and the first winding of common-mode inductor Lc2.

The filter 600 may include a plurality of capacitors, and may include more or fewer capacitors than those shown in FIG. 6.

Additional and components or other arrangement of components may be used to achieve the processes and apparatuses described herein.

Closing Comments

The foregoing is merely illustrative and not limiting, having been presented by way of example only. Although examples have been shown and described, it will be apparent to those having ordinary skill in the art that changes, modifications, and/or alterations may be made.

Although many of the examples presented herein involve specific combinations of elements, it should be understood that those elements may be combined in other ways to accomplish the same objectives. Acts, elements and features discussed only in connection with one embodiment are not intended to be excluded from a similar role in other embodiments.

For means-plus-function limitations recited in the claims, the means are not intended to be limited to the means disclosed herein for performing the recited function, but are intended to cover in scope any means, known now or later developed, for performing the recited function.

As used herein, “plurality” means two or more.

As used herein, a “set” of items may include one or more of such items.

As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

As used herein, “and/or” means that the listed items are alternatives, but the alternatives also include any combination of the listed items.

It is claimed:

1. A filter for reducing electromagnetic interference generated by a power converter, the filter comprising:
a first common-mode inductor comprising first and second windings on a common core
the first winding connected between a first power input line and a first input to the power converter
the second winding connected between a second power input line and a second input to the power converter
a first combination of a first resistor and a first voltage limiting device connected in series, the first combination connected in parallel with the first winding.

2. The filter of claim 1, further comprising:
a second combination of a second resistor and a second voltage limiting device connected in series, the second combination connected in parallel with the second winding.

3. The filter of claim 1, the common-mode inductor further comprising:
a third winding on the common core
the third winding connected between a third power input line and a third input to the power converter.

4. The filter of claim 3, further comprising:
a second combination of a second resistor and a second voltage limiting device connected in series, the second combination connected in parallel with the second winding
a third combination of a third resistor and a third voltage limiting device connected in series, the third combination connected in parallel with the third winding.

5. The filter of claim 3, further comprising:
a first X capacitor connected between the first input to the power converter and the second input to the power converter
a second X capacitor connected between the first input to the power converter and the third input to the power converter
a third X capacitor connected between the second input to the power converter and the third input to the power converter.

6. The filter of claim 1, further comprising:
an X capacitor connected between the first input to the power converter and the second input to the power converter.

7. The filter of claim 1, further comprising:
one or more Y capacitors connected between the power converter and a ground.

8. The filter of claim 7, wherein
the one or more Y capacitors comprise
a first Y capacitor connected between the first input to the power converter and the ground
a second Y capacitor connected between the second input to the power converter and the ground.

9. The filter of claim 7, wherein
the one or more Y capacitors comprise
a Y capacitor connected between an output of a bridge rectifier within the power converter and the ground.

10. The filter of claim 8, wherein
a time constant of the first resistor and the first Y capacitor is less than or equal to the rise time of a largest anticipated common-mode voltage surge.

11. The filter of claim 8, wherein
a time constant of the first resistor and the first Y capacitor is between 33% and 100% of the rise time of a largest anticipated common-mode voltage surge.

12. The filter of claim 1, wherein
the first power input line and the second power input line comprise an AC power source.

13. The filter of claim 1, wherein
the first power input line and the second power input line comprise a DC power source.

14. The filter of claim 3, wherein
the first power input line, the second power input line, and the third power input line comprise a three-phase AC power source.

15. The filter of claim 1, wherein
the voltage limiting device is selected from the group consisting of a silicon transient suppressor, a transorb, back-to-back zener diodes, a varistor, or a gas tube.

16. The filter of claim 1, further comprising
a second common-mode inductor comprising third and fourth windings on a common core
the third winding connected between the first power input line and the first winding
the fourth winding connected between the second power input line and the second winding.

17. The filter of claim 16, further comprising
a second combination of a second resistor and a second voltage limiting device connected in series, the second combination connected in parallel with the third winding or the fourth winding.

18. The filter of claim 16, wherein the first series combination is connected in parallel with the series combination of the first winding and the third winding.

19. A circuit for minimizing the impact of common-mode voltage surges, comprising:
an EMI filter including a common-mode inductor having a plurality of windings
a combination of a resistor and a voltage limiting device in series, the combination connected in parallel with a winding of the common-mode inductor.

20. A method of minimizing the impact of common-mode voltage surges in an EMI filter including a common-mode inductor, the method comprising:
connecting a series combination of a resistor and a voltage limiting device in parallel with a winding of the common-mode inductor.
